(19) United States
(12) Patent Application Publication
(10) Pub. No.: US 2003/0173980 A1
(43) Pub. Date: Sep. 18, 2003

(54) Concentration detector

(76) Inventor: Cyril Ward Nugent, Hampshire (GB)

Correspondence Address: WARE FRESSOLA VAN DER SLUYS &, ADOLPHSON, LLP, BRADFORD GREEN BUILDING 5, 755 MAIN STREET, P O BOX 224, MONROE, CT, 06468, US

(21) Appl. No.: 10/343,899

(22) PCT Filed: Aug. 1, 2001
(86) PCT No.: PCT/GB01/03419

(30) Foreign Application Priority Data
Aug. 4, 2000 (GB) 0019132.0

(51) Int. Cl. G01R 27/26

(52) U.S. Cl. 324/658

(57) ABSTRACT

A transducing device of a concentration detector consists of a non-metallic tube (1), forming a receptacle through which a sample can flow, and two plates in the form of windings of copper foil (2, 3). A de-gausing metallic enclosure (5) surrounds the copper strip windings. To power the transducer, a voltage controller (21) drives an oscillator (22), which triggers a current application circuit (23). The latter has a two connections (24, 25)—pins (1 and 2)—to the respective plates (2, 3). One is at virtual ground potential the other has a steady current applied to it. The voltage between plates is shown in FIG. 4. An output (26)—pin (6)—from the current application circuit is connected to a rectifier (27), in turn connected to an analogue to digital converter (28) from which the output can be input to processsing equipment such as a computer.

The present invention relates to a concentration detector, particular although not exclusively for detecting differences in liquid concentrations, that is to say the concentration of a solute or suspended matter in a liquid—usually water.

There are numerous applications for concentration detectors, for instance in quality control of processes and in monitoring effluent. Measurement of concentration by discrete sampling lends itself to many different forms of measurement. However, in many applications, continuous monitoring is preferable, whereby an alarm can be triggered if the concentration of a liquid flow falls outside desired tolerances. It is particularly advantageous if the monitoring can be effected non-intrusively, that is without withdrawing a sample of the liquid being monitored.

The object of the present invention is to provide an improved concentration detector.

According to the invention there is provided a detector for detecting concentration of a substance in a sample the detector comprising:

a receptacle for the sample;

a pair of plates arranged for field effect from them to impinge on the sample;

a circuit adapted and arranged to apply periodically a steady current to one of the capacitive plates with the other being held at zero potential, the arrangement being such that close to the end of each charging cycle the voltage on the plate being charged steps to a rail voltage of the circuit and remains there until the end of the cycle,

means for measuring the step within the charging cycle.

It is acknowledged that this is an unusual effect, in that a steady current applied to a two plate device will normally result in a steady rise in voltage to the rail voltage without a step in accordance with the capacitance of the plates. It is believed that the effect is connected to the occurrence of nuclear magnetic resonance in the sample. The field effect may therefore be magnetic and/or electric. However, the plates are thought of as capacitive plates.

The preferred current application circuit is a dual monostable multivibrator micro-circuit. A particular circuit, which has been found to be suitable is the HCF4098B circuit manufactured by SGS-Thomson Microelectronics.

The pair of capacitive plates can be configured as two flat plates having interdigitated fingers and set out on a glass plate on the opposite side of which the sample is, the glass plate forming one side of the receptacle. However, this arrangement provides a weak response and the preferred arrangement is for the sample to be within a tubular receptacle—of plastics material or glass for instance—and for the capacitive plates to be provided in around the tube, the two plates being slightly separated along the tube. Preferably the plates extend through more than 360° whereby the ends of each plate overlap. Preferably the plates overlap by a number of turns. Up to twenty turns have provided the effect of the invention. Preferably each plate has between two and four turns. It is believed that this contributes an inductive factor contributing to nuclear magnetic resonance of the sample.

Conveniently, the plates can be provided as windings of copper strip having a self adhesive coating, which secures the copper in position.

The measuring means may be arranged to measure other parameters of the step. However, preferably it measures the width of the step within the cycle. Conveniently this is by production of a square wave initiated at the beginning of the step and terminated at the end of the step and rectification of the resultant signal.

Usually the plates will be provided within a de-gaussing arrangement. This can take the form of further, inter-connected copper windings up- and down-stream of the main windings and additional windings spaced outwardly of the main windings. Alternatively, it can take the form of a metallic enclosure of the main windings.

To help understanding of the invention, a specific embodiment thereof will now be described by way of example and with reference to the accompanying drawings, in which:

FIG. 1 is a perspective view of a transducing device of a concentration detector of the invention, with a de-gaussing enclosure partially cut away;

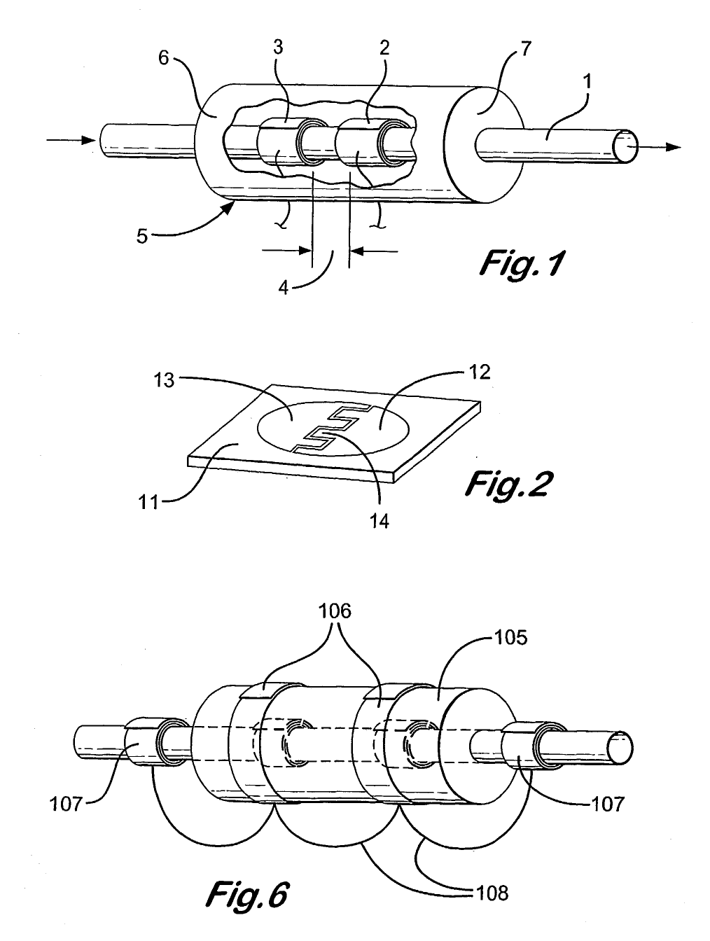

FIG. 2 is a perspective view of an alternative transducing device;

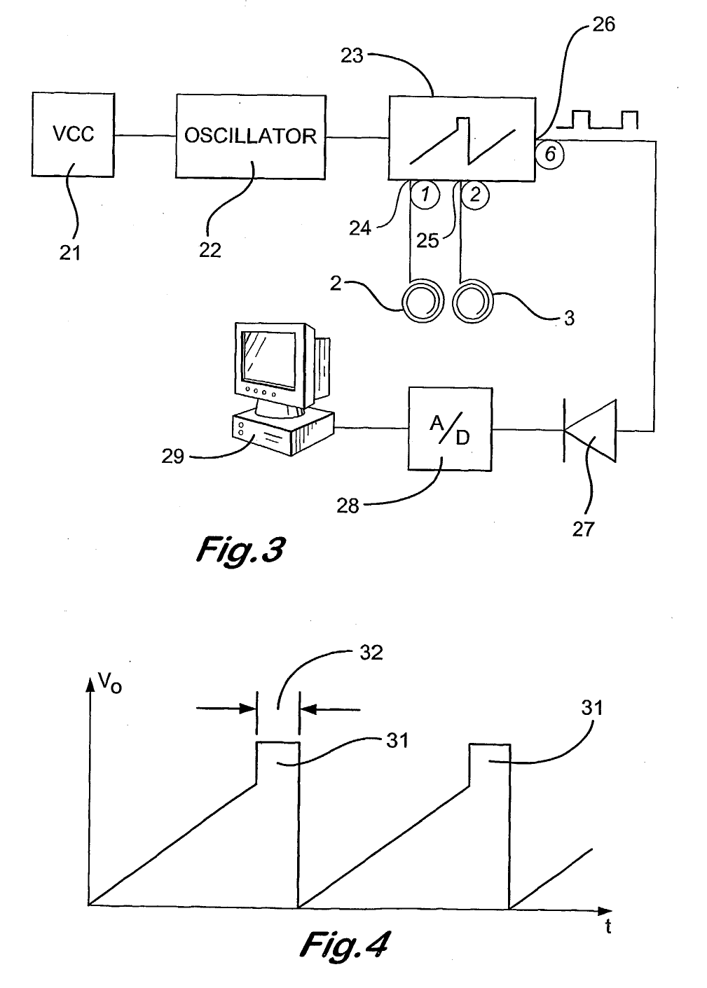

FIG. 3 is a block diagram of the concentration detector;

FIG. 4 is a graph of voltage across the plates of the transducing device;

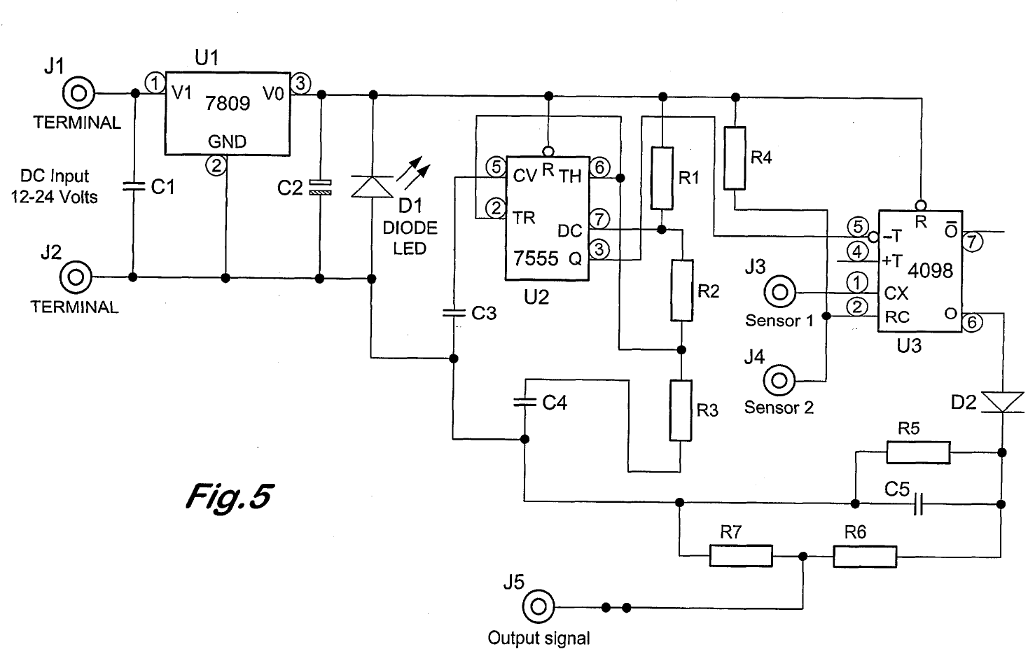

FIG. 5 is a preferred circuit diagram and

FIG. 6 is a view similar to FIG. 1 of a variant.

Referring to first to FIG. 1, a transducing device of a concentration detector is thereshown, consisting of a non-metallic tube 1, typically of polypropylene or glass, having a 10 mm outside diameter and forming a receptacle through which a sample can flow, and two plates in the form of windings of copper foil 2, 3. The foil is 10 mm wide and has a self-adhesive backing. The windings can be separated by as small a gap 4 as 2 mm and as large a gap as 25 mm. It is envisaged that smaller and larger gaps will also be effective. Small gaps provide better results than large gaps. Each winding can typically have between two and four turns. The minimum number of turns is one. Poor results can be expected if the ends of the strips do not overlap, i.e. if there is not a full turn. The device is likely to require more turns, say up to twenty, for monitoring gases as opposed to liquids. Larger diameter tubes have been tested satisfactorily, typically three turns for tubes of 12.5 mm and 50 mm.

Also shown in FIG. 1 is a de-gaussing metallic enclosure 5 around the copper strip windings. This a metal tube 6 with end caps 7, through which the tube 1 passes.

Turning now to FIG. 2 is an alternative arrangement of a glass plate 11, with two copper plates 12, 13 adhered thereto. The plates have interdigitated fingers 14, enhancing their interaction. The plate can be used as the base of a dish onto which a sample can be poured, or the plate can be built into the side of a flow conduit.

In FIG. 3 is shown a block diagram of the circuitry of the detector. A voltage controller 21 powers an oscillator 22, which triggers a current application circuit 23. The latter has a two connections 24, 25—pins 1 and 2—to the respective plates 2, 3. One is at virtual ground potential the other has a steady current applied to it. The voltage between plates is shown in FIG. 4. An output 26—pin 6—from the current application circuit is connected to a rectifier 27, in turn connected to an analogue to digital converter 28 from which the output can be input to processing equipment such as a computer 29.

Details of the circuits are shown in FIG. 5. The components have the following values:

| Component | Value |
|---|---|
| C1 | 100 nF |
| U1 | 7809 microcircuit |
| D1 | LED |
| C2 | 10 μF |
| C3 | 0.1 μF |
| U2 | 7555 microcircuit |
| C4 | 200 pF |
| R1 | 3 kΩ |
| R2 | 3 kΩ |
| R3 | 1.5 Ω |
| R4 | 56 kΩ |
| U3 | 4098 microcircuit |
| D2 | 1n4148 diode |
| R5 | 100 kΩ |
| C5 | 0.1 μF |
| R6 | 100 kΩ |
| R7 | 100 kΩ |

J1 & J2 have 12 volts applied to them. J3 & J4 have windings 2, 3 connected to them and J5 is connected to the analogue to digital converter 28.

The voltage controller has a 7809 chip U1, the oscillator has a 7555 chip U2 and the current application circuit has a 4098 dual monostable multivibrator chip U3. Only one half of the chip is shown in use. However the other half can be used to power a second detection device such as that shown in FIG. 1.

In use, the oscillator is tuned to the order of 350 kHz by adjustment if necessary of the values of R1, R2, R3 & C4. At this frequency, the voltage on pin 2 connected to the winding 2 rises steadily during the first part of each oscillation cycle, but steps to the rail voltage towards the end, typically 1/15 from the end. At the end of the cycle the voltage is reset to ground. The step is referred to as a pedestal 31. The width 32 of the pedestal is determined by the concentration of the sample in the tube 1.

The signal on pin 6 is a square wave having pulse widths equal to the width 32 of the pedestal. Thus rectification of the signal provides a DC signal indicative of the width of the pedestal.

In use, the liquid to be monitored is flowed through the tube. When the liquid—if aqueous—is relatively dilute, the pedestal is relatively wide. When the concentration of solute rises, the pedestal narrows.

The invention is not intended to be restricted to the details of the above described embodiment. For instance, FIG. 6 shows a varied de-gaussing arrangement, with the transducing copper foil windings being within a plastics material enclosure 105, having further copper foil windings 106 on it. Further windings 107 are provided up- and down stream and all these windings are interconnected 108.

1. A detector for detecting concentration of a substance in a fluid, the detector comprising:
a receptacle for the fluid;
a pair of plates arranged for field effect from them to impinge on the fluid;
a circuit adapted and arranged to apply periodically a steady current to one of the capacitive plates with the other being held at zero potential, the arrangement being such that close to the end of each charging cycle the voltage on the plate being charged steps to a rail voltage of the circuit and remains there until the end of the cycle,
means for measuring the step within the charging cycle.

2. A detector as claimed in claim 1, wherein the current application circuit is a dual monostable multivibrator microcircuit.

3. A detector as claimed in claim 2, wherein the dual the monostable multivibrator microcircuit is a HCF4098B circuit.

4. A detector as claimed in claim 1, claim 2 or claim 3, wherein the pair of field effect plates are two flat plates having interdigitated fingers.

5. A detector as claimed in claim 4, wherein the field effect plates are set out on a glass plate on the opposite side of which the fluid is, the glass plate forming one side of the receptacle.

6. A detector as claimed in claim 1, claim 2 or claim 3, wherein the receptacle is tubular and the pair of field effect plates are provided around the tubular receptacle, the two plates being slightly separated along the tube.

7. A detector as claimed in claim 6, wherein the plates extend through more than 360° whereby the ends of each plate overlap.

8. A detector as claimed in claim 7, wherein the plates overlap by a number of turns, preferably up to twenty turns.

9. A detector as claimed in claim 8, wherein each plate has between two and four turns.

10. A detector as claimed in any one of claims 6 to 10, wherein the plates are provided as windings of copper strip having a self adhesive coating, which secures the copper in position.

11. A detector as claimed in any one of claims 6 to 11, wherein the tubular receptacle is of plastics material or glass.

12. A detector as claimed in any preceding claim, wherein the measuring means is arranged to measure the extent of the rail voltage step within the cycle.

13. A detector as claimed in claim 12, wherein the measuring means includes a square wave generator arranged to produce a square wave initiated at the beginning of the step and terminated at the end of the step and a rectifier arranged to rectify the square wave signal.

14. A detector as claimed in any preceding claim, including de-gaussing means at the pair of plates.

15. A detector as claimed in claim 14 as appendant to anyone of claims 6 to 13, wherein the de-gaussing means is in the form of further copper windings up- and down-stream of the main windings and additional windings spaced outwardly of the main windings.

16. A detector as claimed in claim 14 as appendant to anyone of claims 6 to 13, wherein the de-gaussing means is in the form of a metallic enclosure of the main windings.
